(19) United States
(12) Patent Application Publication
(10) Pub. No.: US 2007/0152280 A1
(43) Pub. Date: Jul. 5, 2007

(54) Semiconductor memory device with triple well structure and method of manufacturing the same

(75) Inventors: Jung-Hwa Lee, Suwon-si (KR); Jae-Young Lee, Suwon-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/649,774

(22) Filed: Jan. 5, 2007

(30) Foreign Application Priority Data
Jan. 5, 2006 (KR) 10-2006-0001355

(51) Int. Cl. H01L 29/76; H01L 21/8238

(52) U.S. Cl. 257/371; 438/223; 257/E27.067

(57) ABSTRACT

A semiconductor memory device may include a semiconductor substrate that may have a first conductivity type. A first buried layer may be formed in the semiconductor substrate and may have a second conductivity type opposite to the first type conductivity. A first well may be formed on the first buried layer and may have the first type conductivity. A second well may be formed in the first well over a first surface portion of the first buried layer and may have the second conductivity type. A second buried layer may be formed in the first well and on a second surface portion of the first buried layer and may have the first conductivity type. A third well may be formed in the first well and on the second buried layer and may have the second conductivity type.

This U.S. non-provisional application claims benefit of priority under 35 U.S.C. § 119 to Korean Patent Application No. 10-2006-0001355, filed on Jan. 5, 2006 in the Korean Intellectual Property Office (KIPO), the contents of which are herein incorporated by reference in their entirety.

### BACKGROUND

1. Field

Example embodiments relate to a well structure used in semiconductor memory devices, for example, a triple well structure used to form MOS transistors included in memory core regions.

2. Description of the Related Art

A memory core of a semiconductor memory device may include memory cell arrays, bitline sense amplifiers, and/or sub-wordline driving circuits. A bias voltage of an N well, in which a PMOS transistor included in a bitline sense amplifier or a memory cell array may be formed, may be different from a bias voltage of an N well, in which a PMOS transistor included in a sub-wordline driving circuit may be formed. For example, a bias voltage of an N well associated with a bitline sense amplifier may be an internal supply voltage VINTA or a supply voltage VDD applied from an exterior of a memory chip, whereas a bias voltage of an N well associated with a sub-wordline driving circuit may be a boosted voltage VPP.

FIG. 1 is a cross-sectional view illustrating a vertical structure of transistors included in a memory cell array and a sub-wordline driving circuit of a conventional semiconductor memory device.

Referring to FIG. 1, a conventional semiconductor memory device may include a P-type semiconductor substrate 17, deep N wells 14a and 14b that may be buried layers formed in the P-type semiconductor substrate 17, N wells 12, 15 and 16 and P wells 11 and 13 that may be formed in the P-type semiconductor substrate 17, a P well 10a that may be formed in the deep N well 14a and a P well 10b that may be formed in the deep N well 14b. NMOS transistors constituting a memory cell array MCA may be formed in the P wells 10a and 10b, a PMOS transistor constituting a sub-wordline driving circuit SWD may be formed in the N well 12, and NMOS transistors constituting the sub-wordline driving circuit SWD may be formed in the P wells 11 and 13. The P-type semiconductor substrate 17 may be biased with a ground voltage VSS, the buried layers, for example, the deep N wells 14a and 14b, may be biased with a supply voltage VDD, and the P wells 10a and 10b may be provided with a back-bias voltage VBB. The N well 12, in which the PMOS transistor constituting the sub-wordline driving circuit SWD may be formed, may be biased with a boosted voltage VPP. The N-type wells 15 and 16, and the buried layers, for example, the N wells 14a and 14b, may be formed so as to separate the P wells 10a and 10b, in which MOS transistors constituting the memory cell array MCA may be formed, and the MOS transistors constituting the sub-wordline driving circuit SWD from the P-type semiconductor substrate 17. The deep N wells 14a and 14b and the N well 12 may be isolated from each other. The N wells 14a and 14b may be biased with the supply voltage VDD, and the N well 12 may be biased with the boosted voltage VPP.

FIG. 2 is a cross-sectional view illustrating a vertical structure of transistors included in a memory cell array and a sense amplifier of another conventional semiconductor memory device.

Referring to FIG. 2, a boosted voltage VPP may be applied to an N well 22, in which a MOS transistor constituting a bitline sense amplifier may be formed, and may be applied to a buried layer, for example, an N well 24. Thus, the N well 24 may not be divided and may be formed through an entire region of a memory cell array MCA and the sense amplifier S/A.

In a semiconductor memory device having a triple well structure, according to an example embodiment as shown in FIG. 1, the buried layers, for example, the N wells 14a and 14b, may be isolated from each other and the N wells 15 and 16 may be additionally needed, thus an area of the memory core in semiconductor integrated circuits may be increased. In a semiconductor memory device having a triple well structure, according to an example embodiment as shown in FIG. 2, the N well 22, in which the PMOS transistor constituting the bitline sense amplifier may be formed, may be biased with the boosted voltage VPP. The boosted voltage VPP may be higher than the supply voltage VDD, and may cause a problem of, for example, increasing a body effect of the PMOS transistor formed in the N well 22.

### SUMMARY

Example embodiments may provide a semiconductor memory device having a triple well structure, in which deep wells may not be separated from each other, and wells in which MOS transistors may be formed to constitute a memory core may be electrically isolated from each other.

Example embodiments may provide a method of manufacturing a semiconductor memory device having a triple well structure, in which deep wells may not separated from each other and wells of MOS transistors constituting a memory core may be electrically isolated from each other.

In an example embodiment, a semiconductor memory device may include a semiconductor substrate that may have a first type conductivity. A first buried layer may be formed in the semiconductor substrate and may have a second type conductivity opposite to the first type conductivity. A first well may be formed on the first buried layer and may have the first type conductivity. The second well may be formed in the first well over a first surface portion of the first buried layer and may have the second type conductivity. The second buried layer may be formed in the first well and on a second surface portion of the first buried layer and may have the first type conductivity. The third well may be formed in the first well and on the second buried layer and may have the second type conductivity.

According to an example embodiment, the second well may be formed on the first surface portion and may be electrically connected to the first buried layer.

According to an example embodiment, the third well may be electrically isolated from the first buried layer.

According to an example embodiment, the first type conductivity may correspond to a P-type conductivity and the second type conductivity may correspond to an N-type conductivity.

According to an example embodiment, a first PMOS transistor may be formed in the second well and may be included in the sub-wordline driving circuit, and a second PMOS transistor may be formed in the third well and may be included in the sense amplifier.

According to an example embodiment, a first PMOS transistor may be formed in the third well and may be included in a sub-wordline driving circuit, and a second PMOS transistor may be formed in the second well and may be included in a sense amplifier.

According to an example embodiment, a third buried layer may be formed in the first well interposed between the second well and the first surface portion of the first buried layer, and may have the first type conductivity.

According to an example embodiment, the third well may be electrically isolated from the first buried layer.

According to an example embodiment, the first type conductivity may correspond to a P-type and a second type conductivity may correspond to an N-type.

According to an example embodiment, a first PMOS transistor may be formed in the second well and may be included in a sub-wordline driving circuit, and a second PMOS transistor may be formed in the third well and may be included in a sense amplifier.

According to an example embodiment, a first PMOS transistor may be formed in the third well and may be included in the sub-wordline driving circuit, and a second PMOS transistor may be formed in the second well and may be included in a sense amplifier.

In an example embodiment, a method of manufacturing a semiconductor memory device may include forming a first buried layer of a first type conductivity in a semiconductor substrate; forming a first well of a second type conductivity opposite to the first type conductivity on the first buried layer; forming a second well of the first type conductivity in the first well and over a first surface portion of the first buried layer; forming a second buried layer in the first well and on a second surface portion of the first buried layer; and forming a third well of the first type conductivity in the first well and on the second buried layer.

According to an example embodiment, the second well may be formed on the first surface portion and may be electrically connected to the first buried layer.

According to an example embodiment, the third well may be formed by using a same mask as used to form the second buried layer.

According to an example embodiment, the method may further include forming a third buried layer in the first well interposed between the second well and the first surface portion of the first buried layer. The second buried layer and the third buried layer may be isolated from each other.

According to an example embodiment, the second well and the third well may be formed by using the same mask as used to form the second buried layer and the third buried layer.

Accordingly, the wells in which MOS transistors may be formed to constitute a memory core region may be electrically isolated from each other so that the wells may be biased with voltages different from each other

In an example embodiment, a method of driving a semiconductor memory device including a semiconductor substrate having a first type conductivity, a first buried layer formed in the semiconductor substrate and having a second type conductivity opposite to the first type conductivity, a first well formed on the first buried layer and having the first type conductivity, a second well formed in the first well over a first surface portion of the first buried layer and having the second type conductivity, a second buried layer formed in the first well and on a second surface portion of the first buried layer and having the first type conductivity, and a third well formed in the first well and on the second buried layer and having the second type conductivity, may be provided. The method may include biasing the first buried layer with a first supply voltage; biasing the first well with a second supply voltage that may be lower than a ground voltage; biasing the second well with the first supply voltage; and biasing the third well with a third supply voltage.

According to an example embodiment, the third supply voltage may be lower than the first supply voltage.

According to an example embodiment, the second supply voltage may be a back bias voltage used in the semiconductor memory device.

According to an example embodiment, the first supply voltage may be a boosted voltage used in a sub-wordline driving circuit of the semiconductor memory device and the third supply voltage may be a supply voltage used in a sense amplifier of the semiconductor memory device.

According to an example embodiment, the third supply voltage may be higher than the first supply voltage.

According to an example embodiment, the third supply voltage may be a boosted voltage used in a sub-wordline driving circuit of the semiconductor memory device and the second supply voltage may be a supply voltage used in a sense amplifier of the semiconductor memory device.

In an example embodiment, a method of biasing a semiconductor memory device including a semiconductor substrate having a first type conductivity, a first buried layer formed in the semiconductor substrate and having a second type conductivity opposite to the first type conductivity, a first well formed on the first buried layer and having the first type conductivity, a second well formed in the first well over a first surface portion of the first buried layer and having the second type conductivity, a second buried layer formed in the first well on a second surface portion of the first buried layer and having the first type conductivity; and a third well formed in the first well and interposed between the second well and the first surface portion of the first buried layer and having the second type conductivity may be provided. The method may include biasing the first buried layer with a first supply voltage; biasing the first well with a second supply voltage that may be lower than a ground voltage; biasing one of the second well and third well with the first supply voltage; and biasing the other one of the second well and third well with a third supply voltage that may be lower than the first supply voltage.

According to an example embodiment, the second supply voltage may be a back bias voltage used in the semiconductor memory device.

According to an example embodiment, the first supply voltage may be a boosted voltage used in a sub-wordline driving circuit of the semiconductor memory device and the third supply voltage may be a supply voltage used in a sense amplifier of the semiconductor memory device.

### BRIEF DESCRIPTION OF THE DRAWINGS

Example embodiments will be described with reference to the accompanying drawings.

FIG. 1 is a cross-sectional view illustrating a vertical structure of transistors included in a memory cell array and a sub-wordline driving circuit of a conventional semiconductor memory device.

FIG. 2 is a cross-sectional view illustrating a vertical structure of transistors included in a memory cell array and a sense amplifier of another conventional semiconductor memory device.

FIG. 3 is a diagram illustrating a layout of a semiconductor memory device according to an example embodiment.

FIG. 4 is a diagram illustrating a portion of a memory core included in the semiconductor memory device in FIG. 3.

FIG. 5 is a cross-sectional view illustrating a vertical structure of transistors of a semiconductor memory device according to an example embodiment.

FIG. 6 is a cross-sectional view illustrating a vertical structure of a P-channel MOS transistor formed in an N well of the sub-wordline driving circuit SWD in FIG. 5.

FIG. 7 is a cross-sectional view illustrating a vertical structure of a P-channel MOS transistor formed in an N well of the sense amplifier S/A in FIG. 5.

FIG. 8 is a cross-sectional view illustrating a vertical structure of transistors of a semiconductor memory device according to another example embodiment.

FIG. 9 is a cross-sectional view illustrating a vertical structure of transistors of a semiconductor memory device according to a further example embodiment.

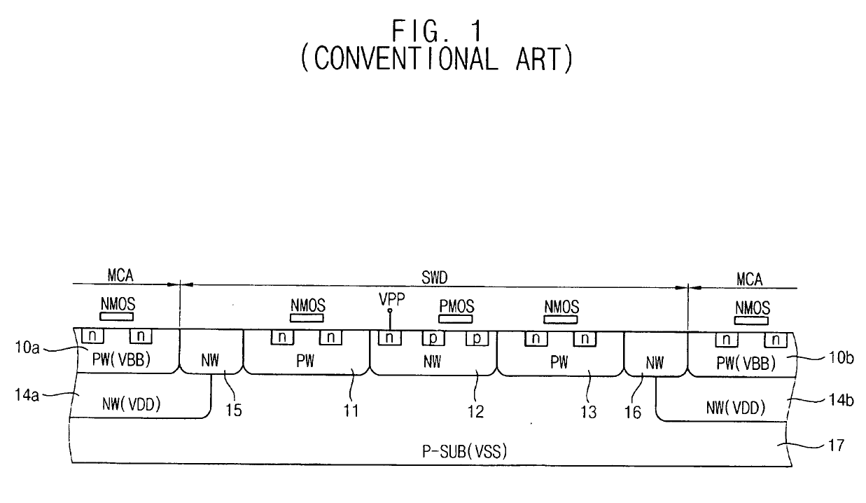

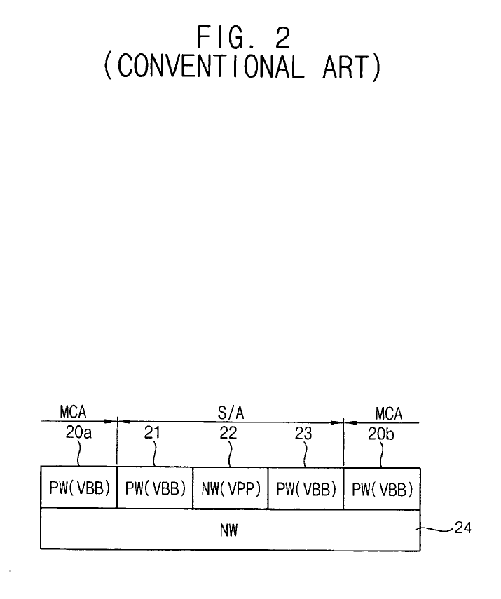

### DESCRIPTION OF EXAMPLE EMBODIMENTS

Example embodiments are disclosed herein. However, specific structural and functional details disclosed herein are merely representative for purposes of describing example embodiments. Example embodiments may, however, be embodied in many alternate forms and should not be construed as limited to the example embodiments set forth herein.

Accordingly, while example embodiments are susceptible to various modifications and alternative forms, specific example embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the spirit and scope. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is for the purpose of describing example embodiments only and is not intended to be limiting. As used herein, the singular forms “a”, “an” and “the” are intended to include the plural forms as well, unless the context clearly indicates otherwise. It will be further understood that the terms “comprises”, “comprising”, “includes” and “including”, when used herein, specify the presence of stated features, integers, steps, operations, elements, and components, but do not preclude the presence or addition of one or more other features, integers, steps, operations, elements, components, and groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

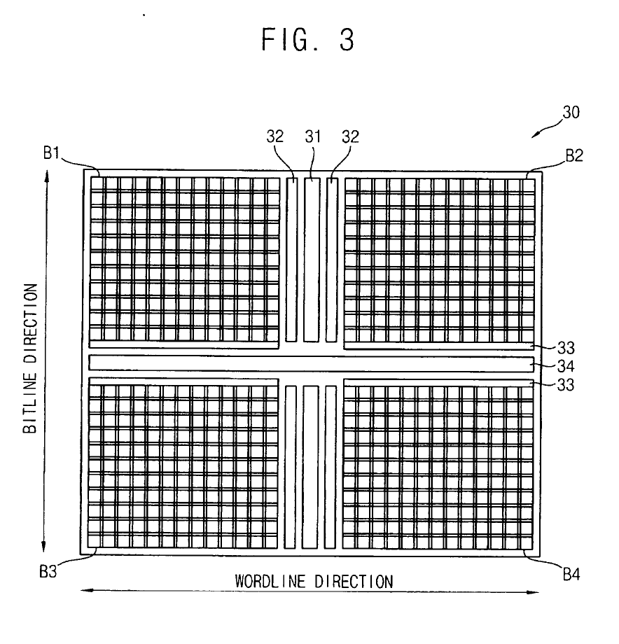

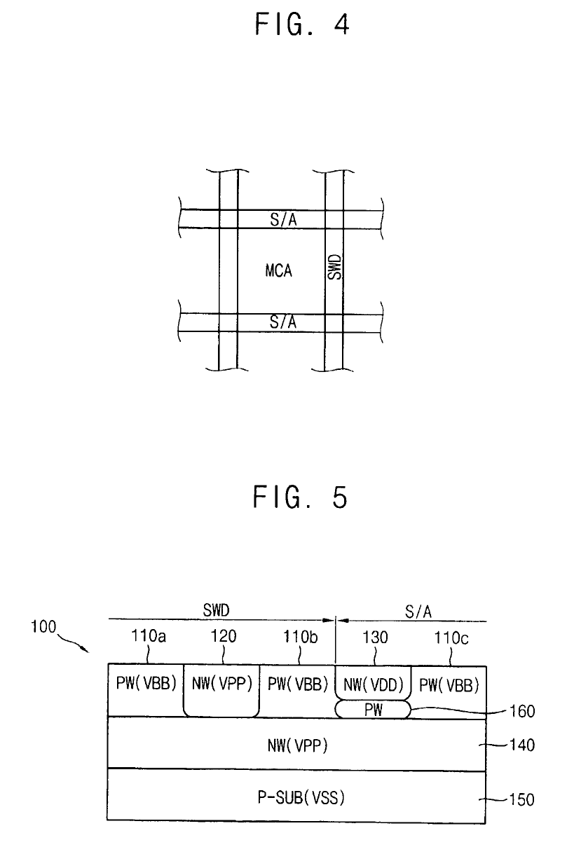

FIG. 3 is a diagram illustrating a layout of a semiconductor memory device according to an example embodiment. FIG. 4 is a diagram illustrating a portion of a memory core included in the semiconductor memory device in FIG. 3.

Referring to FIG. 3, a semiconductor memory device 30 may include four memory banks B1 through B4, a main row decoder region 31, a main wordline driver region 32, a column decoder region 33, and/or a peripheral circuit region 34. A vertical direction of the semiconductor memory device 30 may indicate a bitline direction and a horizontal direction of the semiconductor memory device 30 may indicate a wordline direction.

Referring to FIG. 4, a memory core may include a memory cell array MCA, a sense amplifier S/A, and/or a sub-wordline driving circuit SWD.

FIG. 5 is a cross-sectional view illustrating a vertical structure of transistors of a semiconductor memory device according to an example embodiment. The transistors may constitute a sub-wordline driving circuit SWD and a sense amplifier S/A of the semiconductor memory device.

Referring to FIG. 5, a semiconductor memory device 100 may include a P-type semiconductor substrate 150, a first buried layer 140, a first well 110, a second well 120, a second buried layer 160, and/or a third well 130.

The first buried layer 140 may be formed in the semiconductor substrate 150 and may have an N-type conductivity. The first well 110 may be formed on the first buried layer 140 and may have a P-type conductivity. The second well 120 may be formed in the first well 110 and on a surface portion of the first buried layer 140. The second well 120 may be connected to the first buried layer 140 and may have an N-type conductivity. The second buried layer 160 of a predetermined or desired height may be formed in the first well 110 and on a surface portion of the first buried layer 140, and may have a P-type conductivity. The third well 130 may be formed in the first well 110 and on the second buried layer 160, and may have an N-type conductivity. A height of the second buried layer 160 may be lower than a height of the second well 120.

The second well 120 may be a region for the PMOS transistor constituting the sub-wordline driving circuit SWD and the third well 130 may be a region for the PMOS transistor constituting the sense amplifier S/A.

The semiconductor substrate 150 may be biased with a ground voltage VSS, the first buried layer 140 may be biased with a boosted voltage VDD, and the first well 110 may be biased with a back-bias voltage VBB that may be lower than the ground voltage VSS. The second well 120 may be biased with the boosted voltage VPP, and the third well 130 may be biased with the supply voltage VDD that may be lower than the boosted voltage VPP.

The P-type buried layer 160 may be formed between the first buried layer 140 and the third well 130 so that the third well 130 may be electrically isolated from the first buried layer 140. Thus, the third well 130 may be biased with a bias voltage different from that of the second well 120. For example, the N well 120 in which the PMOS transistor constituting the sub-wordline driving circuit SWD may be formed may be biased with the boosted voltage VPP, and the N well 130 in which the PMOS transistor constituting the sense amplifier S/A may be formed may be biased with the supply voltage VDD that may be lower than the boosted voltage VPP.

A semiconductor memory device, according to an example embodiment as shown in FIG. 5, may be manufactured by forming a first buried layer 140 of an N-type conductivity in the semiconductor substrate 150; forming a first well 110 of a P-type conductivity on the first buried layer 140; forming a second well 120 of an N-type conductivity in the first well 110 such that the second well 120 may be connected to the first buried layer 140; forming a second buried layer 160 of a predetermined or desired height in the first well 110 and on a surface portion of the first buried layer 140; and forming a third well 130 of an N-type conductivity in the first well 110 and on the second buried layer 160. For example, the second buried layer 160 may be formed by an ion implantation process. For example, the third well 130 may be formed by using the same mask as used to form the second buried layer 160.

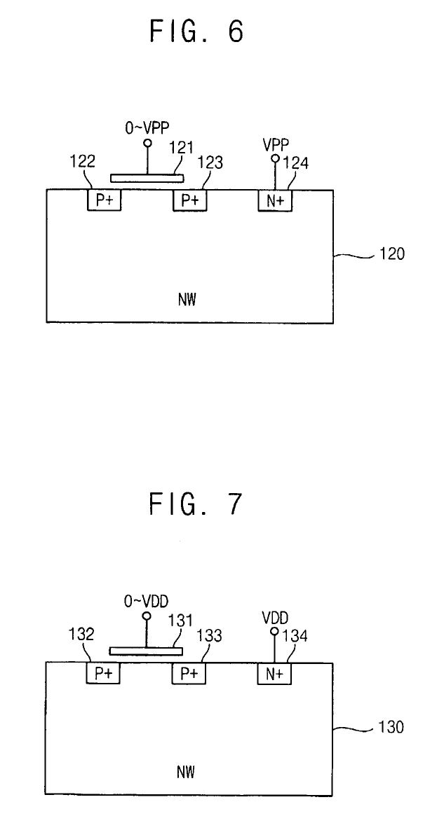

FIG. 6 is a cross-sectional view illustrating a vertical structure of a P-channel MOS transistor formed in an N well of the sub-wordline driving circuit SWD in FIG. 5.

Referring to FIG. 6, a source region 122 and a drain region 123 may be formed by heavily doping P-type impurities into the second well 120 of an N-type conductivity to constitute a PMOS transistor. A gate terminal 121 of the PMOS transistor may be biased with a voltage ranging from OV to the boosted voltage VPP. A contact region 124 may be formed by heavily doping N-type impurities into the second well 120 and may be biased with the boosted voltage VPP.

FIG. 7 is a cross-sectional view illustrating a vertical structure of a P-channel MOS transistor formed in an N well of the sense amplifier S/A in FIG. 5.

Referring to FIG. 7, a source region 132 and a drain region 133 may be formed by heavily doping P-type impurities into the third well 130 of an N-type conductivity to constitute a PMOS transistor. A gate terminal 131 of the PMOS transistor may be biased with a voltage ranging from OV to the supply voltage VDD. A contact region 124 may be formed by heavily doping N-type impurities into the second well 120 and may be biased with the supply voltage VDD.

The PMOS transistor as shown in FIG. 6 may be a transistor constituting the sub-wordline driving circuit SWD. The second well 120 may be biased with the boosted voltage VPP that may be higher than the supply voltage VDD, and a signal applied to the gate 121 of the PMOS transistor may shift fully up to the boosted voltage VPP.

The PMOS transistor as shown in FIG. 7 may be a transistor constituting the sense amplifier S/A. The third well 130 may be biased with the supply voltage VDD that may be lower than the boosted voltage VPP, and a signal applied to the gate 131 of the PMOS transistor may shift fully up to the supply voltage VDD.

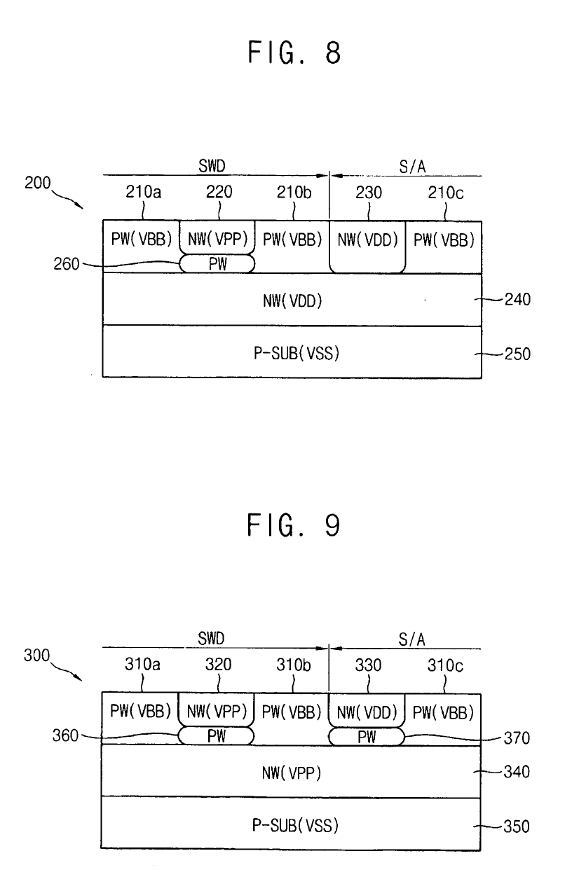

FIG. 8 is a cross-sectional view illustrating a vertical structure of transistors of a semiconductor memory device according to another example embodiment. The transistors may constitute a sub-wordline driving circuit SWD and a sense amplifier S/A of the semiconductor memory device.

Referring to FIG. 8, a semiconductor memory device 200 may include a P-type semiconductor substrate 250, a first buried layer 240, a first well 210, a second well 230, a second buried layer 260, and/or a third well 220.

The first buried layer 240 may be formed in the semiconductor substrate 250 and may have an N-type conductivity. The first well 210 may be formed on the first buried layer 240 and may have a P-type conductivity. The second well 230 may be formed in the first well 210 and on a surface portion of the first buried layer 240. The second well 230 may be connected to the first buried layer 240 and may have an N-type conductivity. The second buried layer 260 of a predetermined or desired height may be formed in the first well 210 and on a surface portion of the first buried layer 240 and may have a P-type conductivity. The third well 220 may be formed in the first well 210 and on the second buried layer 260 and may have an N-type conductivity. A height of the second buried layer 260 may be lower than a height of the second well 230.

The second well 230 may be a region for a PMOS transistor constituting a sense amplifier S/A and the third well 220 may be a region for a PMOS transistor constituting a sub-wordline driving circuit SWD.

The semiconductor substrate 250 may be biased with a ground voltage VSS, the first buried layer 240 may be biased with a supply voltage VDD, and the first well 210 may be biased with a back bias voltage VBB that may be lower than the ground voltage. The second well 230 may be biased with the supply voltage VDD and the third well 220 may be biased with a boosted voltage VP that may be higher than the supply voltage VDD.

The P-type buried layer 260 may be formed between the first buried layer 240 and the third well 220 so that the third well 220 may be electrically isolated from the first buried layer 240. Thus, the second well 230 may be biased with a voltage different from that of the third well 220. For example, the N-type third well 220 in which the PMOS transistor constituting the sub-wordline driving circuit SWD may be formed may be biased with the boosted voltage VPP, and the N-type second well 230 in which the PMOS transistor constituting the sense amplifier S/A may be formed may be biased with supply voltage VDD that may be lower than the boosted voltage VPP.

A semiconductor memory device, according to an example embodiment as shown in FIG. 8, may be manufactured by forming a first buried layer 240 of an N-type conductivity in the semiconductor substrate 250; forming a first well 210 of a P-type conductivity on the first buried layer 240; forming a second well 230 of an N-type conductivity in the first well 210 such that the second well 230 may be connected to the first buried layer 240; forming a second buried layer 260 of a predetermined or desired height in the first well 210 and on a surface portion of the first buried layer 240; and forming a third well 220 of an N-type conductivity in the first well 210 and on the second buried layer 260. For example, the second buried layer 260 may be formed by an ion implantation process. For example, the third well 220 may be formed by using the same mask as used to form the second buried layer 260.

FIG. 9 is a cross-sectional view illustrating a vertical structure of transistors of a semiconductor memory device according to a further example embodiment. The transistors may constitute a sub-wordline driving circuit SWD and a sense amplifier S/A of the semiconductor memory device.

Referring to FIG. 9, a semiconductor memory device 300 may include a P-type semiconductor substrate 350, a first buried layer 340, a first well 310, a second buried layer 360, a second well 320, a third buried layer 370, and/or a third well 330.

The first buried layer 340 may be formed in the semiconductor substrate 350 and may have an N-type conductivity. The first well 310 may be formed on the first buried layer 340 and may have a P-type conductivity. The second buried layer 360 of a predetermined or desired height may be formed in the first well 310 and on a surface portion of the first buried layer 340, and may have a P-type conductivity. The second well 320 may be formed in the first well 310 and on the second buried layer 360, and may have an N-type conductivity. The third buried layer 370 of a predetermined or desired height may be formed in the first well 310 and on a surface portion of the first buried layer 340, and may have a P-type conductivity. The third well 330 may be formed in the first well 310 and on the third buried layer 370, and may have an N-type conductivity.

The second well 320 may be a region for PMOS transistor constituting a sub-wordline driving circuit SWD and the third well 330 may be a region for PMOS transistor constituting a sense amplifier S/A.

The P-type buried layers 360 and 370 may be formed between the first buried layer 340 and the second well 320, and between the first buried layer 340 and the third well 330, respectively, so that the second well 320 and the third well 330 may be electrically isolated from the first buried layer 340. Thus, the second well 320 may be biased with a bias voltage different from that of the third well 330. For example, the N well 320 in which a PMOS transistor constituting a sub-wordline driving circuit SWD may be formed may be biased with a boosted voltage VPP, and the N well 330 in which a PMOS transistor constituting a sense amplifier S/A may be formed may be biased with a supply voltage VDD that may be lower than the boosted voltage VPP.

A semiconductor memory device, according to a further example embodiment as shown in FIG. 9, may be manufactured by forming a first buried layer 340 of an N-type conductivity in the semiconductor substrate 350; forming a first well 310 of a P-type conductivity on the first buried layer 340; forming a second buried layer 360 and the third buried layer 370 of a predetermined or desired height in the first well 310 and on surface portions of the first buried layer 340; forming a second well 320 of an N-type conductivity in the first well 310 and on the second buried layer 360; and forming a third well 330 of an N-type conductivity in the first well 310 and on the third buried layer 370. For example, the second buried layer 360 and a third buried layer 370 may be formed by an ion implantation process. For example, the second well 320 and the third well 330 may be formed by using the same mask as used to form the second buried layer 360 and the third buried layer 370.

As described above, in a semiconductor memory device according to an example embodiment, wells in which MOS transistors may be formed to constitute a memory core region may be electrically isolated from each other so that the wells may be biased with voltages different from each other. Further, characteristics of transistors formed in a well may not be degraded and may be integrated in a chip without increasing a chip size.

Having thus described example embodiments, it is to be understood that the appended claims are not to be limited by particular details set forth in the above description as many apparent variations thereof are possible without departing from the spirit or scope thereof as hereinafter claimed.

What is claimed is:

1. A semiconductor memory device comprising:
a semiconductor substrate having a first type conductivity;
a first buried layer formed in the semiconductor substrate and having a second type conductivity opposite to the first type conductivity;
a first well formed on the first buried layer and having the first type conductivity;
a second well formed in the first well over a first surface portion of the first buried layer and having the second type conductivity;
a second buried layer formed in the first well and on a second surface portion of the first buried layer and having the first type conductivity; and
a third well formed in the first well and on the second buried layer and having the second type conductivity.

2. The semiconductor memory device of claim 1, wherein the second well is formed on the first surface portion and electrically connected to the first buried layer.

3. The semiconductor memory device of claim 2, wherein the third well is electrically isolated from the first buried layer.

4. The semiconductor memory device of claim 2, wherein the first type conductivity corresponds to a P-type conductivity and the second type conductivity corresponds to an N-type conductivity.

5. The semiconductor memory device of claim 2, further comprising a first PMOS transistor formed in the second well and included in a sub-wordline driving circuit, and a second PMOS transistor formed in the third well and included in a sense amplifier.

6. The semiconductor memory device of claim 2, further comprising a first PMOS transistor formed in the third well and included in a sub-wordline driving circuit, and a second PMOS transistor formed in the second well and included in a sense amplifier.

7. The semiconductor memory device of claim 1, further comprising
a third buried layer formed in the first well interposed between the second well and the first surface portion of the first buried layer and having the first type conductivity.

8. The semiconductor memory device of claim 7, wherein the third well is electrically isolated from the first buried layer.

9. The semiconductor memory device of claim 7, wherein the first type conductivity corresponds to a P-type and the second type conductivity corresponds to an N-type.

10. The semiconductor memory device of claim 7, further comprising=a first PMOS transistor formed in the second well and included in a sub-wordline driving circuit, and a second PMOS transistor formed in the third well and included in a sense amplifier.

11. The semiconductor memory device of claim 7, further comprising a first PMOS transistor formed in the third well and included in a sub-wordline driving circuit, and a second PMOS transistor formed in the second well and included in a sense amplifier.

12. A method of manufacturing a semiconductor memory device comprising:
forming a first buried layer of a first type conductivity in a semiconductor substrate;
forming a first well of a second type conductivity opposite to the first type conductivity on the first buried layer;
forming a second well of the first type conductivity in the first well over a first surface portion of the first buried layer;
forming a second buried layer in the first well and on a second surface portion of the first buried layer; and
forming a third well of the first type conductivity in the first well and on the second buried layer.

13. The method of claim 12, wherein the second well is formed on the first surface portion and electrically connected to the first buried layer.

14. The method of claim 12, wherein the third well is formed by using a same mask as used to form the second buried layer.

15. The method of claim 12, further comprising forming a third buried layer in the first well interposed between the second well and the first surface portion of the first buried layer, the second buried layer and the third buried layer being isolated from each other.

16. The method of claim 15, wherein the second well and the third well are formed by using a same mask as used to form the second buried layer and the third buried layer.

17. A method of driving a semiconductor memory device including a semiconductor substrate having a first type conductivity, a first buried layer formed in the semiconductor substrate and having a second type conductivity opposite to the first type conductivity, a first well formed on the first buried layer and having the first type conductivity, a second well formed in the first well over a first surface portion of the first buried layer and having the second type conductivity, a second buried layer formed in the first well and on a second surface portion of the first buried layer and having the first type conductivity, and a third well formed in the first well and on the second buried layer and having the second type conductivity, the method comprising:
biasing the first buried layer with a first supply voltage;
biasing the first well with a second supply voltage that is lower than a ground voltage;
biasing the second well with the first supply voltage; and
biasing the third well with a third supply voltage.

18. The method of claim 17, wherein the third supply voltage is lower than the first supply voltage.

19. The method of claim 18, wherein the second supply voltage is a back bias voltage used in the semiconductor memory device.

20. The method of claim 18, wherein the first supply voltage is a boosted voltage used in a sub-wordline driving circuit of the semiconductor memory device and the third supply voltage is a supply voltage used in a sense amplifier of the semiconductor memory device.

21. The semiconductor memory device of claim 17, wherein the third supply voltage is higher than the first supply voltage.

22. The semiconductor memory device of claim 21, wherein the third supply voltage is a boosted voltage used in a sub-wordline driving circuit of the semiconductor memory device and the second supply voltage is a supply voltage used in a sense amplifier of the semiconductor memory device.

23. A method of biasing a semiconductor memory device including a semiconductor substrate having a first type conductivity, a first buried layer formed in the semiconductor substrate and having a second type conductivity opposite to the first type conductivity, a first well formed on the first buried layer and having the first type conductivity, a second well formed in the first well over a first surface portion of the first buried layer and having the second type conductivity, a second buried layer formed in the first well on a second surface portion of the first buried layer and having the first type conductivity; and a third well formed in the first well and interposed between the second well and the first surface portion of the first buried layer and having the second type conductivity, the method comprising:
biasing the first buried layer with a first supply voltage;
biasing the first well with a second supply voltage that is lower than a ground voltage;
biasing one of the second well and third well with the first supply voltage; and
biasing the other one of the second well and third well with a third supply voltage lower than the first supply voltage.

24. The method of claim 23, wherein the second supply voltage is a back bias voltage used in the semiconductor memory device.

25. The method of claim 23, wherein the first supply voltage is a boosted voltage used in a sub-wordline driving circuit of the semiconductor memory device and the third supply voltage is a supply voltage used in a sense amplifier of the semiconductor memory device.
